(19) United States
(12) Patent Application Publication
(10) Pub. No.: US 2025/0258293 A1
(43) Pub. Date: Aug. 14, 2025

(54) ULTRASONIC SENSOR HAVING ACTIVATABLE NOTCH FILTER

(71) Applicant: VALEO SCHALTER UND SENSOREN GMBH, Bietigheim-Bissingen (DE)

(72) Inventors: Philipp Maurer, Bietigheim-Bissingen (DE); Martin Walger, Bietigheim-Bissingen (DE)

(73) Assignee: VALEO SCHALTER UND SENSOREN GMBH, Bietigheim-Bissingen (DE)

(21) Appl. No.: 18/850,055

(22) PCT Filed: Mar. 15, 2023
(86) PCT No.: PCT/EP2023/056551

§ 371 Date: Sep. 24, 2024

(30) Foreign Application Priority Data
Mar. 25, 2022 (DE) 10 2022 107 066.2

(51) Int. Cl. G01S 15/931; B06B 1/02; G01S 7/527; H03H 7/01; H03H 7/06

(52) U.S. Cl. CPC G01S 15/931; B06B 1/0215; G01S 7/527; H03H 7/06; B06B 2201/55; H03H 2007/013

(57) ABSTRACT

The invention relates to an ultrasonic sensor (14) for emitting ultrasonic signals and for receiving ultrasonic echoes, in particular for use on a vehicle (10), having an ultrasound diaphragm, a piezoelectric element (26) mounted on the ultrasound diaphragm, an amplifier circuit (36), and connection circuitry (28), which electrically connects the piezoelectric element (26) and the amplifier circuit (36), wherein the connection circuitry (28) comprises an activatable notch filter (38) having a filter frequency (f_{F}), and the ultrasonic sensor (14) is designed to activate the notch filter (38) in the event of interference in the region of the filter frequency (f_{F}) during reception of the ultrasonic echoes. The invention also relates to an ultrasonic detection system (50) having a plurality of ultrasonic sensors (14) for detecting an environment (24), in particular an environment (24) of a vehicle (10), on the basis of sensor information provided by the ultrasonic sensors (14), having a plurality of ultrasonic sensors (14) that are connected to each other via a data link (18), wherein one of the ultrasonic sensors (14) is in the form of a master (M) in order to receive the sensor information from at least one further ultrasonic sensor (14), which is in the form of a slave(S), and to process this sensor information in order to detect the environment (24) of the vehicle (10), wherein the ultrasonic sensors (14) are embodied as specified above. In addition, the invention relates to a driving assistance system (12) having at least one ultrasonic sensor (14) for providing sensor information, and having a control unit (16), wherein the at least one ultrasonic sensor (14) and the control unit (16) are connected to each other via a data link (18), and the control unit (16) is designed to receive the sensor information from the at least one ultrasonic sensor (14) and to process this sensor information in order to detect the environment (24) of the vehicle (10), wherein the at least one ultrasonic sensor (14) is embodied as specified above.

The present invention relates to an ultrasonic sensor for emitting ultrasonic signals and for receiving ultrasonic echoes, in particular for use on a vehicle, having an ultrasound diaphragm, a piezoelectric element mounted on the ultrasound diaphragm, an amplifier circuit, and connection circuitry, which electrically connects the piezoelectric element and the amplifier circuit.

In addition, the present invention relates to an ultrasonic detection system having a plurality of ultrasonic sensors for detecting an environment, in particular an environment of a vehicle, on the basis of sensor information provided by the ultrasonic sensors, having a plurality of ultrasonic sensors, which are connected to each other via a data link, wherein one of the ultrasonic sensors is in the form of a master in order to receive the sensor information from at least one further ultrasonic sensor, which is in the form of a slave, and to process this sensor information in order to detect the environment of the vehicle.

The present invention also relates to a driving assistance system having at least one ultrasonic sensor for providing sensor information, and having a control unit, wherein the at least one ultrasonic sensor and the control unit are connected to each other via a data link, and the control unit is designed to receive the sensor information from the at least one ultrasonic sensor and to process this sensor information in order to detect the environment of the vehicle.

Ultrasonic sensors emit ultrasonic pulses, which are reflected as ultrasonic echoes by objects in the environment. These ultrasonic echoes can be received by the ultrasonic sensors to detect distances from the objects to the ultrasonic sensors from a time difference between the emission of ultrasonic pulses and the reception of ultrasonic echoes.

Such ultrasonic sensors are currently used in numerous driving assistance systems in vehicles to perform various functions, for example to detect parking spaces, measure parking spaces, monitor distances to obstacles during a parking maneuver, or to monitor a blind spot of the vehicle while driving. The driving assistance systems can be in the form of driver assistance systems for assisting a human vehicle driver in driving the vehicle or else for providing an assistance function for autonomous driving functions.

The ultrasonic sensors comprise an ultrasound diaphragm, mounted on which is a piezoelectric element that performs an electromechanical energy conversion and converts ultrasonic signals into electrical signals. These electrical signals are fed via connection circuitry to an amplifier, which provides from the electrical signals a receive signal, for example as an envelope. In the latest ultrasonic sensors, ultrasonic pulses are also emitted via the same ultrasound diaphragm.

The ultrasonic sensors typically work on one or more channels in a narrow frequency band lying in the region of approximately 50 kHz. When there is more than one channel, the channels typically lie in a region of a few kilohertz around approximately 50 kHz. For example, a single-channel ultrasonic sensor can transmit and receive at a center frequency of approximately 51 kHz, whereas in the case of a multichannel ultrasonic sensor, a first channel can lie at a center frequency of 51 kHz, while a second receive channel is offset by 3 kHz, so for instance lies at 48 kHz or 54 kHz. In principle, two channels having center frequencies of 48 kHz and 54 kHz can also be used. It is also possible to switch between the channels.

The detection of the ultrasound echo is performed digitally, i.e. a receive signal from the ultrasonic sensor is sampled and quantized after amplification. According to the sampling theorem, this requires a sampling frequency that is at least twice as high as the signal frequency, so approximately 100 kHz minimum. In practice, however, significantly higher sampling frequencies are used to detect the ultrasonic echoes.

Electromagnetic interference can arise during operation of the ultrasonic sensors, for instance as a result of inductive charging of electric vehicles, with this interference typically occurring at a frequency of approximately 150 kHz. In addition, keyless entry systems typically transmit signals at a frequency of approximately 125 kHz, which are radiated by ferrite antennas fitted in door handles and can lead to corresponding interference. Both these examples of interference therefore lie above the minimum sampling frequency. When sampling at high sampling frequencies, for instance in the region of six or eight times the signal frequency, such interference can be identified and suitably processed. This involves high costs for the sampling, however. At a lower sampling frequency, for instance at just a fourfold sampling frequency, this interference can result in alias signals, which are superimposed on the received ultrasonic echoes and hence prevent the ultrasonic sensors from working correctly. Using low-pass filters has proved impractical because these filters are either too expensive or else filter out received ultrasonic echoes as well. This lowers the usable receive level and reduces a maximum range of the ultrasonic sensors.

In this context, EP 1 617 752 B1 discloses a method for determining the resonant frequency of a passive ultrasonic sensor having at least one vibratable part.

WO 2011/163475 A1 discloses analog signal processing in an imaging system, for instance an ultrasound medical imaging system. The system includes multiple controllable input processing blocks, each implementing a discrete time analog signal processing stage such as time domain filtering for fractional time delay, anti-alias filtering, or matched filtering.

Proceeding from the abovementioned prior art, the object of the invention is therefore to specify an ultrasonic sensor and also a driving assistance system having at least one ultrasonic sensor, which are less susceptible to interference and allow a high receive level for received ultrasonic echoes.

The object is achieved according to the invention by the features of the independent claims. Advantageous embodiments of the invention are specified in the dependent claims.

Thus, according to the invention, an ultrasonic sensor for emitting ultrasonic signals and for receiving ultrasonic echoes is specified, in particular for use on a vehicle, having an ultrasound diaphragm, a piezoelectric element mounted on the ultrasound diaphragm, an amplifier circuit, and connection circuitry, which electrically connects the piezoelectric element and the amplifier circuit, wherein the connection circuitry comprises an activatable notch filter having a filter frequency, and the ultrasonic sensor is designed to activate the notch filter in the event of interference in the region of the filter frequency during reception of the ultrasonic echoes.

In addition, according to the invention, an ultrasonic detection system is specified having a plurality of ultrasonic sensors for detecting an environment, in particular an environment of a vehicle, on the basis of sensor information provided by the ultrasonic sensors, having a plurality of ultrasonic sensors, which are connected to each other via a data link, wherein one of the ultrasonic sensors is in the form of a master in order to receive the sensor information from at least one further ultrasonic sensor, which is in the form of a slave, and to process this sensor information in order to detect the environment of the vehicle, wherein the ultrasonic sensors are embodied as specified above.

According to the invention, a driving assistance system is also specified having at least one ultrasonic sensor for providing sensor information, and having a control unit, wherein the at least one ultrasonic sensor and the control unit are connected to each other via a data link, and the control unit is designed to receive the sensor information from the at least one ultrasonic sensor and to process this sensor information in order to detect the environment of the vehicle, wherein the at least one ultrasonic sensor is embodied as specified above.

The fundamental idea of the present invention is thus to design the ultrasonic sensor having an activatable notch filter such that interference occurring at the filter frequency can be filtered out yet, without the notch filter activated, no additional attenuation occurs in the system. Thus such an ultrasonic sensor can activate the notch filter when interference occurs, so that the interference can be filtered out to allow continued reception of ultrasonic echoes. In the event of no interference occurring, the notch filter is not activated and is thus disabled, with the result that, during this normal operation, the received ultrasonic echoes are not additionally attenuated by the notch filter. Such notch filters have a narrow stop band around the filter frequency f_{F}, and therefore the frequency response of a deep notch equates to high selectivity, making the notch filter extremely well suited to filtering out narrow-band interference and attenuating wanted signals only slightly. Therefore the notch filter is particularly good at filtering out known interference sources at a specific interference frequency. Hence it is possible to filter out reliably interference that occurs at a known interference frequency, for instance as a result of inductive charging of electric vehicles, typically at an interference frequency of approximately 150 kHz, or else caused by keyless entry systems, typically at an interference frequency of approximately 125 kHz from ferrite antennas fitted in door handles. Nonetheless, even with highly frequency-selective notch filters, it is only possible at great expense to avoid attenuation that extends into the ultrasonic frequency range of the ultrasonic sensors. Thus it can happen that the wanted signal is also attenuated. This may involve an attenuation of the wanted signal by a few dB, which can still reduce the range of the ultrasonic sensor during normal operation, however. The activation of the notch filter when required, i.e. when interference occurs, can avoid the problem of attenuating the wanted signal during normal operation. Only in the activated state does the notch filter have an influence on the connection circuitry.

In summary, the ultrasonic sensors according to the invention allow reliable operation even, for example, in the vicinity of parked cars, where interference can occur as a result of inductive charging of electric vehicles, typically at a frequency of approximately 150 kHz, or else caused by keyless entry systems, typically at a frequency of approximately 125 kHz by ferrite antennas fitted in door handles. Therefore activating the notch filter can be advantageous particularly in the neighborhood of parking lots, parking blocks or parking garages.

The notch filter cam be implemented simply and at low cost. The notch filter usually comprises passive components, which is particularly advantageous for a simple filter. This applies in particular to the use in ultrasonic sensors, which provide little space for installing filters of complex design.

The ultrasonic sensor can have a standard design. Ultrasonic sensors as such are known in principle, and therefore there is no need to describe them in detail.

The ultrasonic sensor comprises an ultrasound diaphragm for emitting ultrasonic pulses and for receiving ultrasonic echoes. Thus the same diaphragm is used for transmitting ultrasonic pulses as for receiving ultrasonic echoes.

Mounted on the ultrasound diaphragm is the piezoelectric element. In the latest ultrasonic sensors, the piezoelectric element is usually adhesively bonded to the ultrasound diaphragm internally. The piezoelectric element performs an electromechanical energy conversion and converts the received ultrasonic echoes into electrical signals. The connection circuitry typically comprises a coupling capacitor and an RF low-pass filter for filtering out high-frequency interference and for current limiting. The electrical signals are fed to the amplifier circuit via the connection circuitry. The amplifier circuit can amplify the electrical signals and provide a receive signal, for instance as an envelope. The current limiting by the coupling capacitor also works during transmission of the ultrasonic pulses.

Ultrasonic detection systems having a plurality of ultrasonic sensors mounted on a front and/or rear of the vehicle are common today. Such a system can monitor the front or rear of the vehicle for example independently.

In principle, the ultrasonic sensors as master and slave(s) can be identical ultrasonic sensors, differing only in their configuration. Consequently, each of the ultrasonic sensors can be used as a master or slave. The ultrasonic sensors in the form of slaves can be connected via individual data links to the ultrasonic sensor in the form of master, or the ultrasonic sensors in the form of slaves can be connected via a data link in the form of a databus to the ultrasonic sensor in the form of master. A cascaded arrangement of the ultrasonic sensors is preferred. The ultrasonic sensor in the form of master can in turn be connected via a further data link to a higher-level control unit of the vehicle.

The ultrasonic sensor in the form of master receives the sensor information from the at least one ultrasonic sensor in the form of a slave. The ultrasonic sensor in the form of master can receive, for example, envelopes of the received ultrasonic echoes as sensor information from the ultrasonic sensors in the form of slaves, or simply information about relevant received ultrasonic echoes. The ultrasonic sensor in the form of master processes this sensor information in order to detect the environment of the vehicle.

In the driving assistance system can be used a plurality of ultrasonic sensors in order to emit ultrasonic pulses using one or more ultrasonic sensor(s) and to receive their ultrasonic echoes using one or more ultrasonic sensor(s). The emission of ultrasonic pulses can therefore be performed for each ultrasonic sensor independently of receiving the ultrasonic echoes. A design of the ultrasonic sensors is common in which the ultrasonic sensors receive ultrasonic echoes from the ultrasonic pulses that they themselves have emitted. The ultrasonic sensors are again in this case preferably identical.

The driving assistance system can be any driving assistance system that has at least one ultrasonic sensor. Such driving assistance systems can perform various assistance functions, for instance detecting or measuring parking spaces, monitoring distances to obstacles during a parking maneuver, or monitoring a blind spot of the vehicle while driving, to name just some of the currently most widely used functions. The driving assistance system can be in the form of a driver assistance system for assisting a human vehicle driver in driving the vehicle or else for providing an assistance function for autonomous driving functions.

Driving assistance systems having a plurality of ultrasonic sensors mounted on a front and/or rear of the vehicle are common today. In addition, ultrasonic sensors on the sides of vehicles are becoming increasingly common.

The ultrasonic sensors can be connected individually or in groups to the control unit via a data link or via a plurality of data links. In principle, it is also possible that groups of ultrasonic sensors are connected to a control unit independently of other ultrasonic sensors. In this case, a plurality of driving assistance systems, each having a group of ultrasonic sensors, can thus be installed on the vehicle.

The control unit receives the sensor information from the at least one ultrasonic sensor. The control unit can receive, for example, envelopes of the received ultrasonic echoes as sensor information from the ultrasonic sensors, or simply information about relevant received ultrasonic echoes. The control unit processes this sensor information in order to detect the environment of the vehicle.

In an advantageous embodiment of the invention, the activatable notch filter is in the form of a twin-T filter. Such notch filters as twin-T filters have a simple design. Twin-T filters can be realized with just a few different components. Therefore, twin-T filters can be provided at low cost, while also having good frequency-specific attenuation. In a variant, a twin-Pi filter can also be used based on a star-delta transformation.

In an advantageous embodiment of the invention, the activatable notch filter is constructed from identical resistors and/or identical capacitors, wherein the identical resistors and/or the identical capacitors are part of an associated resistor network and/or an associated capacitor network. Resistor networks are also known as resistor arrays and have a plurality of identical individual resistors, which can be connected individually. The same applies to capacitor networks, which are also known as capacitor arrays and have a plurality of identical individual capacitors, which can be connected individually. The number of individual resistors or individual capacitors can be different according to the resistor network or capacitor network respectively. This design can provide a filter very simply and also compactly. Different resistances or capacitances can be realized by connecting in series and/or parallel resistors of the resistor network or capacitors of the capacitor network respectively.

In an advantageous embodiment of the invention, the amplifier circuit is integrated with an application-specific integrated circuit, and the ultrasonic sensor is designed to activate by means of the application-specific integrated circuit the notch filter in the event of interference in the region of the filter frequency during reception of the ultrasonic echoes. Such application-specific integrated circuits are also called ASICs. These application-specific integrated circuits make it straightforward to provide the amplifier circuit with desired properties. The application-specific integrated circuits are typically based on standard designs, allowing additional functions to be provided easily without using other ASICs. Particularly preferably, the amplifier circuit comprises one or more GPIOs (general-purpose input/output), which can be placed appropriately in the application-specific integrated circuits in order to activate the notch filter. For example, by means of the GPIO(s) and at least one switch provided in the application-specific integrated circuit, the notch filter can be connected to ground in order to activate the notch filter. Without this ground connection the notch filter is disabled. Further functions can also be realised easily using GPIOs of the ASIC of the amplifier circuit, as described in the statements below.

In an advantageous embodiment of the invention, the activatable notch filter is integrated with a coupling capacitor of the connection circuitry. The design of the ultrasonic sensor and in particular of the connection circuitry can be simplified in this way, because fewer additional elements are required to realize the notch filter. In addition, the connection circuitry can be more compact overall, which is advantageous in particular when available space is tight. It also means that the notch filter can be integrated easily in the connection circuitry, with the result that, in the inactivated state, an unwanted influence on the electrical signals in the connection circuitry can be avoided. During normal operation, i.e. when the notch filter is in the inactivated state, the coupling capacitor can perform its usual coupling function and/or current limiting.

In an advantageous embodiment of the invention, the notch filter is in the form of a frequency-adjustable notch filter of adjustable filter frequency, and the ultrasonic sensor is designed to adjust the filter frequency of the notch filter according to an interference frequency of the interference during reception of the ultrasonic echoes. For example, the notch filter can be switched between two or more discrete filter frequencies. The discrete filter frequencies can be defined, for example, for different interference frequencies of potential known interference sources. Such a switchover can be realized easily for instance by connecting or disconnecting resistors or capacitors in the notch filter, for example in parallel and/or in series with existing resistors or capacitors. Alternatively, the notch filter can be varied in a defined frequency range, for example, so that the filter frequency can be adjusted in this defined frequency range. The adjustment can be made continuously or discretely, for instance by means of potentiometers or other adjustable components. In particular, the amplifier circuit can be designed to perform the adjustment of the filter frequency of the notch filter. Particularly preferably, the amplifier circuit is integrated with an application-specific integrated circuit having at least one GPIO in order to adjust the filter frequency of the notch filter.

In an advantageous embodiment of the invention, the ultrasonic sensor is designed to receive an activation signal, in particular from a control unit of a driving assistance system, wherein the received activation signal indicates the interference during reception of the ultrasonic echoes, and the ultrasonic sensor is also designed to activate the notch filter depending on the reception of the activation signal. Therefore the notch filter will be activated in the ultrasonic sensor depending on the received activation signal. The activation signal can be an analog signal level or else an item of information transferred as a digital signal via a data link, for instance from a connected control unit. In this case, the activation of the notch filter is carried out without the associated ultrasonic sensor performing the relevant signal processing for determining the interference during reception of the ultrasonic echoes.

In an advantageous embodiment of the invention, the ultrasonic sensor has an interference detection unit, which is designed to determine the interference during reception of the ultrasonic echoes, and the ultrasonic sensor is designed to activate the notch filter depending on the determined interference during reception of the ultrasonic echoes. Thus the activation of the notch filter is carried out on the basis of signal processing by the associated ultrasonic sensor for determining the interference. In the case of a frequency-adjustable notch filter, the interference detection unit can additionally be designed to determine the interference frequency of the interference during reception of the ultrasonic echoes, so that the filter frequency of the notch filter can be adjusted accordingly. Alternatively, the filter frequency of the notch filter can be adjusted on the basis of an external signal received by the ultrasonic sensor.

In an advantageous embodiment of the invention, the notch filter is configurable, and the ultrasonic sensor is designed to configure the notch filter depending on a type of the interference in the region of the filter frequency during reception of the ultrasonic echoes. Analogous to the activation of the notch filter, the ultrasonic sensor can be designed to receive a configuration signal, in particular from a control unit of a driving assistance system, wherein the received configuration signal indicates the type of the interference during reception of the ultrasonic echoes, and the ultrasonic sensor is also designed to configure the notch filter depending on the reception of the configuration signal. Alternatively, the ultrasonic sensor can have an interference detection unit, which is designed to determine the type of the interference during reception of the ultrasonic echoes. The ultrasonic sensor can configure the notch filter on the basis thereof. The configuration can adapt the filter in order to avoid as far as possible an unwanted loss of information through the filter, or at least to reduce this to a necessary amount. The type of the interference can be defined, for example, by an interference frequency, a bandwidth of the interference and/or a level of the interference.

In an advantageous embodiment of the invention, the ultrasonic sensor in the form of master is designed to determine interference in the region of the filter frequency during reception of the ultrasonic echoes, and, depending on the determined interference, to transfer to the at least one ultrasonic sensor in the form of a slave an activation signal indicating the interference in the region of the filter frequency during reception of the ultrasonic echoes, and/or the ultrasonic sensor in the form of master is designed to determine a type of the interference in the region of the filter frequency during reception of the ultrasonic echoes, and, depending on the determined type of the interference, to transfer to the at least one ultrasonic sensor in the form of a slave a configuration signal for configuring the notch filter. Thus the ultrasonic sensor in the form of master can determine whether interference is present during reception of the ultrasonic echoes and/or what type of interference is present during reception of the ultrasonic echoes. This can include the ultrasonic sensor in the form of master determining, for example, an interference frequency of the interference during reception of the ultrasonic echoes. In addition, it is possible to determine a strength of the interference, for instance a level or frequency bandwidth of the interference. The interference and/or the type of the interference can be determined individually for individual ultrasonic sensors or jointly for groups of ultrasonic sensors. The activation signal can accordingly contain additional information relating to the determined interference frequency. Alternatively or additionally, the configuration signal can contain additional information relating to the type of the interference, for example the determined interference frequency, the level or the frequency bandwidth of the interference. The ultrasonic sensor in the form of master can send the activation signal and/or the configuration signal to individual ultrasonic sensors or to groups of ultrasonic sensors configured as slave(s), so that the ultrasonic sensors can activate and/or configure their notch filters individually or in groups. In principle, the ultrasonic sensor in the form of master can receive from a higher-level controller also information about interference and/or a type of the interference during reception of the ultrasonic echoes, and determine therefrom the presence of the interference and/or the type of the interference. The ultrasonic sensor in the form of master can then, as described above, send the activation signal and/or the configuration signal to the ultrasonic sensors in the form of slaves to which it is connected. Then, the ultrasonic sensors in the form of slaves activate their notch filter and, if applicable, enable the filter frequency depending on the activation signal, and/or carry out a configuration of their notch filters. The statements relating to determining the interference and/or the type of the interference apply equally to the master itself and also to ultrasonic sensors connected thereto as slaves.

In an advantageous embodiment of the invention, the control unit is designed to determine interference in the region of the filter frequency during reception of the ultrasonic echoes, and, depending on the determined interference, to transfer to the at least one ultrasonic sensor an activation signal indicating the interference in the region of the filter frequency during reception of the ultrasonic echoes, and/or the control unit is designed to determine a type of the interference in the region of the filter frequency during reception of the ultrasonic echoes, and, depending on the determined type of the interference, to transfer to the at least one ultrasonic sensor a configuration signal for configuring the notch filter. Thus the control unit can determine whether interference is present during reception of the ultrasonic echoes and/or what type of interference is present during reception of the ultrasonic echoes. This can include the control unit determining an interference frequency of the interference during reception of the ultrasonic echoes. In addition, it is possible to determine a strength of the interference, for instance a level or frequency bandwidth of the interference. The interference and/or the type of the interference can be determined individually for individual ultrasonic sensors or jointly for groups of ultrasonic sensors. The activation signal can accordingly contain additional information relating to the determined interference frequency. Alternatively or additionally, the configuration signal can contain additional information relating to the type of the interference, for example the determined interference frequency, the level or the frequency bandwidth of the interference. The control unit can send the activation signal and/or the configuration signal to individual ultrasonic sensors or to groups of ultrasonic sensors, so that the ultrasonic sensors can activate and/or configure their notch filters individually or in groups. In principle, the control unit can receive from a higher-level controller also information about interference and/or a type of the interference during reception of the ultrasonic echoes, and determine therefrom the presence of the interference and/or the type of the interference. The control unit can then, as described above, send the activation signal and/or the configuration signal to the ultrasonic sensors to which it is connected. Then, the ultrasonic sensors activate their notch filter, enable the filter frequency, and/or carry out a configuration of their notch filters depending on the activation signal and/or the configuration signal.

The invention is explained in more detail below with reference to the attached drawing on the basis of preferred embodiments. The features shown can each constitute an aspect of the invention both individually and in combination. Features of different exemplary embodiments can be transferred from one exemplary embodiment to another.

In the drawing:

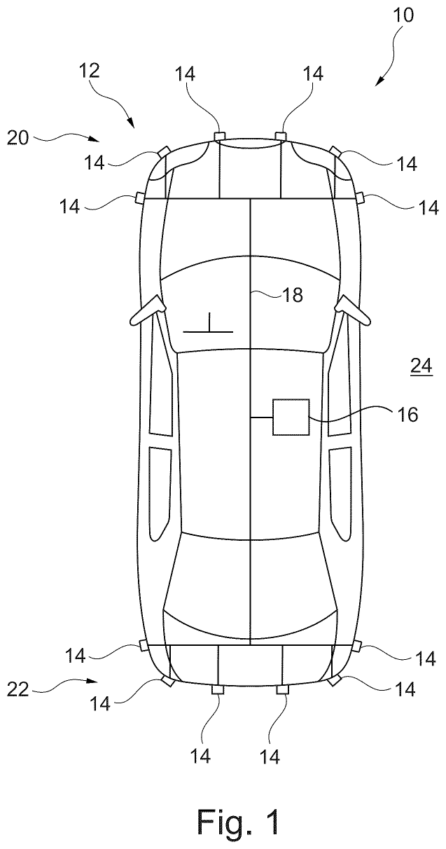

FIG. 1 shows a schematic view of a vehicle having an environment perception system, which comprises ultrasonic sensors and a control unit, which are connected via a data link, according to a first, preferred embodiment;

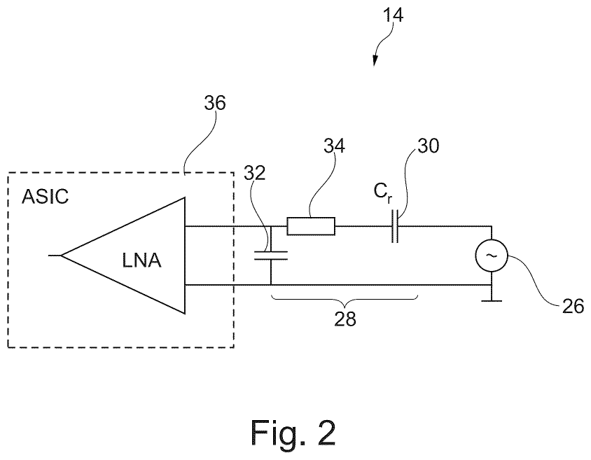

FIG. 2 shows a schematic representation of functional components of an ultrasonic sensor from FIG. 1 during normal operation having a piezoelectric element coupled to an ultrasound diaphragm, and having connection circuitry and an amplifier circuit;

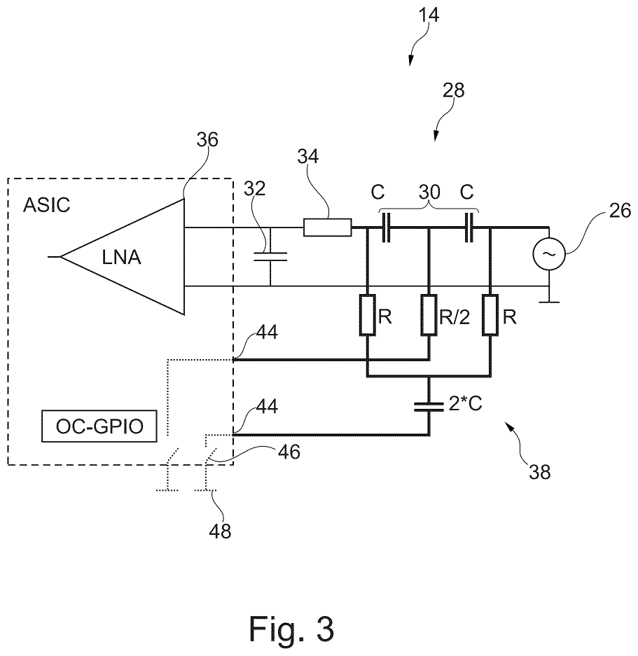

FIG. 3 shows a schematic representation of the functional components of the ultrasonic sensor from FIG. 1 having a notch filter as a twin-T filter according to the first embodiment;

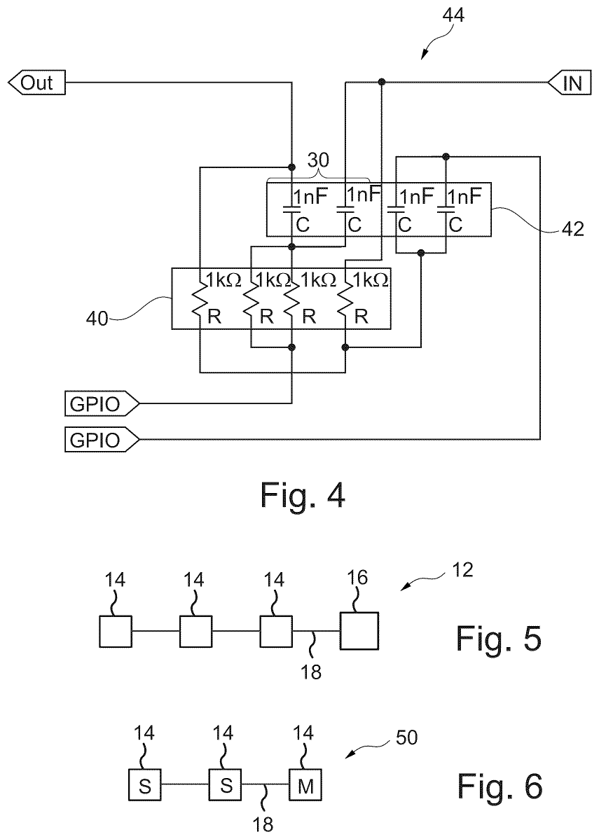

FIG. 4 shows a detailed representation of the notch filter of FIG. 3 having a design based on a resistor network and a capacitor network;

FIG. 5 shows a schematic representation of an environment perception system according to a second embodiment having a plurality of ultrasonic sensors and a control unit, which are connected in a cascade via a data link;

FIG. 6 shows a schematic representation of an ultrasonic detection system according to a third embodiment having a plurality of ultrasonic sensors, which are connected to each other in a cascade via a data link;

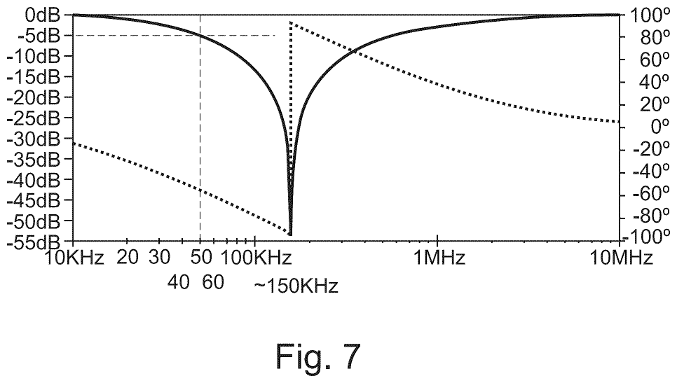

FIG. 7 shows an attenuation curve of the notch filter of FIG. 3 in a configuration as a twin-T filter with a maximum attenuation of over 50 dB at a filter frequency of ˜150 kHz and an attenuation of approximately 5 dB in the region of an ultrasonic frequency of approximately 50 kHz; and

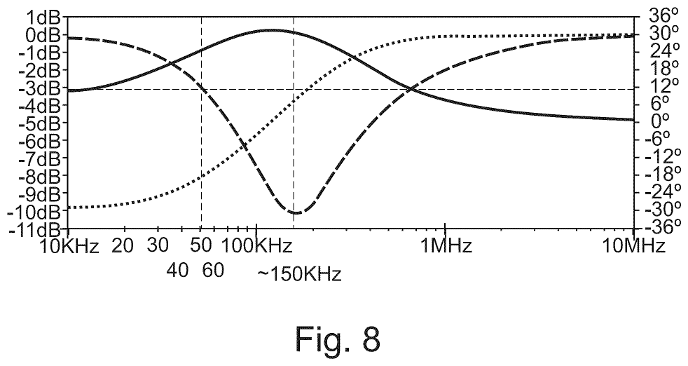

FIG. 8 shows an attenuation curve of the notch filter of FIG. 3 in a configuration as a (single) T filter with a maximum attenuation of approximately 10 dB at a filter frequency of ˜150 kHz and an attenuation of approximately 3 dB in the region of an ultrasonic frequency of approximately 50 kHz.

FIG. 1 shows a vehicle 10 with a driving assistance system 12 according to a first, preferred embodiment. The driving assistance system 12 in this exemplary embodiment is generically an environment perception system, and can be part of a more extensive assistance system.

The driving assistance system 12 comprises a plurality of ultrasonic sensors 14 and a control unit 16, with the ultrasonic sensors 14 and the control unit 16 being connected to each other via a data link 18. The control unit 16 is a data processing unit having a processor and a memory for executing a program stored therein. Such control units 16 are known in the automotive sector also as electronic control units (ECUs). The data link 18 here is in the form of a databus, to which all the ultrasonic sensors 14 and the control unit 16 are jointly connected. Different topologies can be used for the data link 18, and different protocols can be used for the data transfer via this data link, which are known as such in the prior art. In this exemplary embodiment, the data link 18 is designed in accordance with one of the standards CAN, FlexRay, or LON, for example.

The ultrasonic sensors 14 are arranged in two groups of six ultrasonic sensors 14 each along a front 20 and a rear 22 of the vehicle 10. The ultrasonic sensors 14 are designed to monitor an environment 24 of the vehicle 10 and are arranged accordingly on the vehicle 10. The ultrasonic sensors 14 send their sensor information via the data link 18 to the control unit 16, which receives and processes the sensor information in order to detect an environment 24 of the vehicle 10. Hence the driving assistance system 12 is designed in this exemplary embodiment to detect the environment 24 of the vehicle 10.

The detection of the environment 24 of the vehicle 10 by the driving assistance system 12 is performed by the emission of ultrasonic pulses by one or more of the ultrasonic sensors 14. The ultrasonic echoes from these ultrasonic pulses are received by one or more of the ultrasonic sensors 14. Therefore, for each ultrasonic sensor 14, the emission of ultrasonic pulses can be independent of receiving the ultrasonic echoes. Alternatively, the ultrasonic sensors 14 can each receive ultrasonic echoes of the ultrasonic pulses that they themselves emitted.

The control unit 16 receives the sensor information from the ultrasound sensors 14. The control unit 16 can receive, for example, envelopes from the ultrasonic sensors 14, or simply information about relevant received ultrasonic echoes. The control unit 16 processes this sensor information in order to detect the environment 24 of the vehicle 10.

Each of the ultrasonic sensors 14 comprises an ultrasound diaphragm for emitting the ultrasonic pulses and for receiving the ultrasonic echoes, to which diaphragm is coupled a piezoelectric element 26, which is shown schematically in FIG. 2. The piezoelectric element 26 is adhesively bonded to the ultrasound diaphragm internally and performs an electromechanical energy conversion. The same applies to the emission of ultrasonic pulses by each of the ultrasonic sensors 14.

In addition, each of the ultrasonic sensors 14 comprises connection circuitry 28 containing a coupling capacitor 30 and an RF low-pass filter, which is formed by a capacitor 32 and a resistor 34. The RF low-pass filter filters out high-frequency interference. In addition, current limiting is carried out for frequencies typically far above the operating frequency. This design is also shown in FIG. 2. Finally, each of the ultrasonic sensors 14 comprises an amplifier circuit 36. The connection circuitry 28 electrically connects the piezoelectric element 26 and the amplifier circuit 36. During reception of the ultrasonic echoes by the ultrasonic sensor 14, electrical signals produced by the piezoelectric element 26 are fed via the connection circuitry 28 to the amplifier circuit 36. The amplifier circuit 36 amplifies the electrical signals and provides a receive signal, for instance as an envelope. In this exemplary embodiment, the amplifier circuit 36 is implemented by an application-specific integrated circuit (ASIC).

The connection circuitry 28 also comprises an activatable notch filter 38 having a filter frequency f_{F}, which filter is shown in FIG. 3 as part of the connection circuitry 28 and shown alone in FIG. 4. In the representation in FIG. 2, the notch filter 38 is not shown in order to illustrate the state with the notch filter 38 inactivated, in which the notch filter 38 is not operating and does not influence the function of the connection circuitry 28.

The notch filter 38 has a narrow stop band around its filter frequency f_{F}, and therefore the frequency response corresponds to a deep notch with high selectivity. It is thereby possible to filter out interference occurring at a specific interference frequency. In the present exemplary embodiment, the notch filter 38 has a filter frequency f_{F} of approximately 150 kHz, which corresponds to an interference frequency such as that produced by the inductive charging of electric vehicles, for example.

The activatable notch filter 38 here is in the form of a twin-T filter, which can be seen best in FIG. 3. The notch filter 38 is constructed from identical resistors R and identical capacitors C, which are arranged to form a twin-T. Hence the notch filter 38 is constructed from just two different passive components. The identical resistors R are part of a corresponding resistor network 40 containing a total of four identical resistors R. The identical capacitors C are part of a corresponding capacitor network 42 containing a total of four identical capacitors C. Different resistances or capacitances can be realized by connecting in series or parallel resistors R of the resistor network 40 or capacitors C of the capacitor network 42 respectively, as shown in FIGS. 3 and 4. So for instance, the bottom capacitor in FIG. 3 is formed by a parallel connection of two capacitors C of the capacitor network 42, and the central resistor in FIG. 3 is formed by a parallel connection of two resistors R of the corresponding resistor network 40.

The notch filter 38 is integrated with the coupling capacitor 30 of the connection circuitry 28 by the fact that two of the capacitors C of the capacitor network 42, connected in series, form the coupling capacitor 30. Both these capacitors C are an integral part of one of the ‘T’s of the notch filter 38. As can be seen in conjunction with FIG. 2, the two capacitors C also operate as a coupling capacitor 30 when the notch filter 38 is inactivated. The series connection of the two capacitors C means that the coupling capacitor 30 has in total half the capacitance of each of the two capacitors C.

As shown in FIG. 3, the notch filter 38 is integrated in the connection circuitry 28. Thus the notch filter 38 is connected by its terminals IN and OUT between the piezoelectric element 26 and the current limiter 34, and by its terminals GPIO to corresponding outputs of the amplifier circuit 36.

As already discussed above, the amplifier circuit 36 is implemented by an application-specific integrated circuit. The amplifier circuit 36 comprises in this exemplary embodiment two general-purpose inputs/outputs 44 (GPIOs), which can be connected to ground 48 via two switches 46 of the application-specific integrated circuit.

In a normal state, which is shown in FIG. 3, the switches 46 are open, whereby the terminals GPIA of the notch filter 38 are not connected to each other nor to ground 48. In this state, the notch filter 38 is not active, while, as already mentioned, two of the capacitors C of the capacitor network 42 form the coupling capacitor 30. The closure of the two switches 46 of the application-specific integrated circuit connects the terminals GPIO of the notch filter 38 to ground 48, as opposed to the normal state. An electrical connection is also made between the two terminals GIPO of the notch filter 38. In this state, the notch filter 38 is active as a twin-T filter, i.e. is activated, and filters the electrical signal provided by the piezoelectric element 26 according to the filter characteristic shown in FIG. 7. This results in attenuation of over 50 dB of the electrical signal in the region of the filter frequency f_{F}, whereas the wanted ultrasonic signal experiences only an attenuation of approximately 5 dB in the region of 50 kHz.

Alternatively, the notch filter 38 can be configured as a single T-filter when only one of the two terminals GPIO of the notch filter 38 is connected to ground 48, as opposed to the normal state. This is done by opening one of the two switches 46 and closing the other switch 46, with the result that the corresponding terminal GPIO of the notch filter 38 is connected to ground 48 via the closed switch 46, and the other is not. In this state, as a (single) T-filter, the notch filter 38 filters the electrical signal provided by the piezoelectric element 26 according to the filter characteristic shown in FIG. 8. This results in attenuation of approximately 10 dB of the electrical signal in the region of the filter frequency f_{F}, whereas the wanted ultrasonic signal experiences only an attenuation of approximately 3 dB in the region of 50 kHz.

By the actuation of the switches 46, each ultrasonic sensor 14 can thus configure, depending on reception of a relevant configuration signal, the notch filter 38 depending on a type of the interference in the region of the filter frequency f_{F} during reception of the ultrasonic echoes.

The control unit 16 is designed to determine an interference during reception of the ultrasonic echoes, and, depending on the determined interference, to transfer to the ultrasonic sensors 14 an activation signal indicating the interference during reception of the ultrasonic echoes. The control unit 16 is also designed to determine a type of the interference in the region of the filter frequency f_{F} during reception of the ultrasonic echoes, and, depending on the determined type of the interference, to transfer to the ultrasonic sensors 14 a configuration signal for configuring the notch filter 38. Thus the control unit 16 determines whether interference is present during reception of the ultrasonic echoes and what type of interference this is. In this exemplary embodiment, the control unit 16 additionally determines an interference frequency of the interference during reception of the ultrasonic echoes and a strength of the interference, which is defined by a level and frequency bandwidth of the interference. The interference and the type of the interference can be determined individually for individual ultrasonic sensors 14 or jointly for groups of ultrasonic sensors 14. The activation signal and/or the configuration signal can optionally contain additional information relating to the determined interference frequency. The control unit 16 can send the activation signal and/or the configuration signal to individual ultrasonic sensors 14 or to groups of ultrasonic sensors 14, so that the ultrasonic sensors 14 can activate and/or configure their notch filters 38 individually or in groups.

The ultrasonic sensors 14 are designed to receive the activation signal and the configuration signal from the control unit 16 and to activate and configure the notch filter 38 depending on the reception of the activation signal. Therefore the notch filter 38 is activated and also deactivated again in the respective ultrasonic sensors 14 depending on the received activation signal. In the activated state, the notch filter 38 is configured depending on the configuration signal, as was described above.

The activation signal and the configuration signal are items of information, which are transferred as digital signals via the data link 18. The activation signal and the configuration signal can each be transferred in separate messages or in a shared message.

In an alternative embodiment, each ultrasonic sensor 14 has an interference detection unit, which is designed to determine the interference and also the type of the interference during reception of the ultrasonic echoes. In this alternative embodiment, each of the ultrasonic sensors 14 is designed to activate and configure the notch filter 38 automatically depending on the determined interference during reception of the ultrasonic echoes. Thus the activation and configuration of the notch filter 38 is carried out on the basis of signal processing by the associated ultrasonic sensor 14 for determining the interference. In the case of a frequency-adjustable notch filter 38, the interference detection unit can additionally be designed to determine an interference frequency of the interference during reception of the ultrasonic echoes, and to adjust the filter frequency f_{F} of the notch filter 38 accordingly.

FIG. 5 shows a driving assistance system 12 according to a second embodiment. The driving assistance system 12 in the second embodiment can replace the driving assistance system 12 in the first embodiment, where, if applicable, a plurality of driving assistance systems 12 in the second embodiment replace one driving assistance system 12 in the first embodiment. The driving assistance systems 12 in the first embodiment and second embodiment differ solely in how they are connected to each other, as explained below.

The driving assistance system 12 in the second embodiment comprises a plurality of ultrasonic sensors 14 and a control unit 16, with the ultrasonic sensors 14 and the control unit 16 being connected to each other via a data link 18. The data link 18 here is in the form of a cascaded databus, to which all the ultrasonic sensors 14 and the control unit 16 are connected one after the other. Data is accordingly forwarded from one ultrasonic sensor 14 or from the control unit 16 to an adjacent ultrasonic sensor 14 or the adjacent control unit 16 respectively, until this data has reached its recipient.

In the second exemplary embodiment, each group of ultrasonic sensors 14 arranged along the front 20 or rear 22 respectively of the vehicle 10 forms, with one control unit 16 each, an independent driving assistance system 12. Hence one driving assistance system 12 is designed to detect the environment 24 in front of the vehicle 10, and one driving assistance system 12 is designed to detect the environment 24 behind the vehicle 10.

FIG. 6 shows an ultrasonic detection system 50 according to a third embodiment. The ultrasonic detection system 50 in the third embodiment can replace the driving assistance systems 12 in the first or second embodiments, where, if applicable, a plurality of ultrasonic detection systems 50 in the third embodiment replace one driving assistance system 12 in the first embodiment. The ultrasonic detection system 50 differs from the driving assistance systems 12 in that it has no control unit 16.

The ultrasonic detection system 50 comprises a plurality of ultrasonic sensors 14, which are connected to each other via a data link 18. The data link 18 here is in the form of a cascaded databus, to which all the ultrasonic sensors 14 are connected one after the other. Data is accordingly forwarded from one ultrasonic sensor 14 to an adjacent ultrasonic sensor 14 until this data has reached its recipient. As FIG. 6 shows, one of the ultrasonic sensors 14 is in the form of a master M, while the other ultrasonic sensors 14 are in the form of slaves S. The ultrasonic sensor 14 in the form of master M receives the sensor information from the ultrasonic sensors 14 in the form of slaves S, and processes it in order to detect the environment 24 of the vehicle 10.

In the third exemplary embodiment, each group of ultrasonic sensors 14, which are arranged along the front 20 or rear 22 respectively of the vehicle 10, forms an independent ultrasonic detection system 50. Hence one ultrasonic detection system 50 is designed to detect the environment 24 in front of the vehicle 10, and one ultrasonic detection system 50 is designed to detect the environment 24 behind the vehicle 10. The ultrasonic sensors 14 of the ultrasonic detection system 50 have the same design and differ by their configuration as master M or slaves S in order to be able to perform their respective functions.

The ultrasonic detection system 50 differs from the driving assistance system 12 in the second embodiment in that the control unit 16 is omitted. The tasks of the control unit 16 are performed in the ultrasonic detection system 50 accordingly by the ultrasonic sensor 14 in the form of master M.

### LIST OF REFERENCE SIGNS

10 vehicle
12 driving assistance system, environment perception system
14 ultrasonic sensor
16 control unit
18 data link, databus
20 front
22 rear
24 environment
26 piezoelectric element
28 connection circuitry
30 coupling capacitor
32 RF low-pass filter
34 current limiter
36 amplifier circuit
38 notch filter
40 resistor network
42 capacitor network
44 general-purpose input/output
46 switch
48 ground
50 ultrasonic detection system
R resistor
C capacitor
IN terminal
OUT terminal
GPIO terminal
M master
S slave

1. An ultrasonic sensor for emitting ultrasonic signals and for receiving ultrasonic echoes, for use on a vehicle, comprising:
an ultrasound diaphragm;
a piezoelectric element mounted on the ultrasound diaphragm;
an amplifier circuit; and
connection circuitry, which electrically connects the piezoelectric element and the amplifier circuit,
wherein the connection circuitry comprises an activatable notch filter having a filter frequency, and
wherein the ultrasonic sensor is designed to activate the notch filter in the event of interference in the region of the filter frequency during reception of the ultrasonic echoes.

2. The ultrasonic sensor as claimed in claim 1, wherein the activatable notch filter is in the form of a twin-T filter.

3. The ultrasonic sensor as claimed in claim 1,
wherein the activatable notch filter is constructed from identical resistors and/or identical capacitors, wherein the identical resistors and/or the identical capacitors are part of an associated resistor network and/or an associated capacitor network.

4. The ultrasonic sensor as claimed in claim 1,
wherein the amplifier circuit is integrated with an application-specific integrated circuit, and
wherein the ultrasonic sensor is designed to activate by means of the application-specific integrated circuit the notch filter in the event of interference in the region of the filter frequency during reception of the ultrasonic echoes.

5. The ultrasonic sensor as claimed in claim 1,
wherein the activatable notch filter is integrated with a coupling capacitor of the connection circuitry.

6. The ultrasonic sensor as claimed in claim 1,
wherein the notch filter is in the form of a frequency-adjustable notch filter of adjustable filter frequency, and
wherein the ultrasonic sensor is designed to adjust the filter frequency of the notch filter according to an interference frequency of the interference during reception of the ultrasonic echoes.

7. The ultrasonic sensor as claimed in claim 1,
wherein the ultrasonic sensor is designed to receive an activation signal, from a control unit of a driving assistance system, wherein the received activation signal indicates the interference during reception of the ultrasonic echoes, and the ultrasonic sensor is also designed to activate the notch filter depending on the reception of the activation signal.

8. The ultrasonic sensor as claimed in claim 1,
wherein the ultrasonic sensor has an interference detection unit, which is designed to determine the interference during reception of the ultrasonic echoes, and
wherein the ultrasonic sensor is designed to activate the notch filter depending on the determined interference during reception of the ultrasonic echoes.

9. The ultrasonic sensor as claimed in claim 1,
wherein the notch filter is configurable, and
wherein the ultrasonic sensor is designed to configure the notch filter depending on a type of the interference in the region of the filter frequency during reception of the ultrasonic echoes.

10. An ultrasonic detection system having a plurality of ultrasonic sensors for detecting an environment, an environment of a vehicle, on the basis of sensor information provided by the ultrasonic sensors, comprising:
a plurality of ultrasonic sensors, which are connected to each other via a data link, wherein one of the ultrasonic sensors is in the form of a master in order to receive the sensor information from at least one further ultrasonic sensor, which is in the form of a slave, and to process this sensor information in order to detect the environment of the vehicle,
wherein the ultrasonic sensors are embodied as claimed in claim 1.

11. The ultrasonic detection system as claimed in claim 10
wherein the ultrasonic sensor for emitting ultrasonic signals and for receiving ultrasonic echoes, for use on a vehicle, comprising:
an ultrasound diaphragm,
a piezoelectric element mounted on the ultrasound diaphragm,
an amplifier circuit, and
connection circuitry, which electrically connects the piezoelectric element and the amplifier circuit,
wherein the connection circuitry comprises an activatable notch filter having a filter frequency, and
wherein the ultrasonic sensor is designed to activate the notch filter in the event of interference in the region of the filter frequency during reception of the ultrasonic echoes,
wherein the ultrasonic sensor is designed to receive an activation signal, from a control unit of a driving assistance system, wherein the received activation signal indicates the interference during reception of the ultrasonic echoes, and the ultrasonic sensor is also designed to activate the notch filter depending on the reception of the activation signal,
wherein the ultrasonic sensor in the form of master is designed to determine interference in the region of the filter frequency during reception of the ultrasonic echoes, and, depending on the determined interference, to transfer to the at least one ultrasonic sensor in the form of a slave an activation signal indicating the interference in the region of the filter frequency during reception of the ultrasonic echoes, and/or
wherein the ultrasonic sensor in the form of master is designed to determine a type of the interference in the region of the filter frequency during reception of the ultrasonic echoes, and, depending on the determined type of the interference, to transfer to the at least one ultrasonic sensor in the form of a slave a configuration signal for configuring the notch filter.

12. A driving assistance system comprising:
at least one ultrasonic sensor for providing sensor information; and
a control unit,
wherein the at least one ultrasonic sensor and the control unit are connected to each other via a data link, and the control unit is designed to receive the sensor information from the at least one ultrasonic sensor, and to process this sensor information in order to detect the environment of the vehicle,
wherein the at least one ultrasonic sensor is embodied as claimed in claim 1.

13. (canceled)
